(19) United States
(12) Patent Application Publication
(10) Pub. No.: US 2025/0370077 A1
(43) Pub. Date: Dec. 4, 2025

(54) MAGNETIC RESONANCE IMAGING METHOD AND MAGNETIC RESONANCE IMAGING SYSTEM

(71) Applicant: GE Precision Healthcare LLC, Waukesha, WI (US)

(72) Inventors: Ting Zhang, Beijing (CN); Yao Ding, Beijing (CN); Yongchuan Lai, Beijing (CN); Xiaocheng Wei, Beijing (CN); Teresa Weng, Beijing (CN)

(21) Appl. No.: 19/222,000

(22) Filed: May 29, 2025

(30) Foreign Application Priority Data
May 29, 2024 (CN) 202410683036.8

(51) Int. Cl. G01R 33/54

(52) U.S. Cl. CPC G01R 33/543

(57) ABSTRACT

A magnetic resonance imaging method and a magnetic resonance imaging system is provided. The method includes: adjusting a waveform of a gradient pulse in a scan sequence according to a signal acquisition time window, wherein the signal acquisition time window at least includes at least part of the gradient rise and gradient fall times of the gradient pulse; and generating and transmitting a scan sequence with an adjusted waveform, acquiring a magnetic resonance signal in the signal acquisition time window, and reconstructing a magnetic resonance image according to the magnetic resonance signal.

### CROSS REFERENCE TO RELATED APPLICATIONS

The present application claims priority and benefit of Chinese Patent Application No. 202410683036.8 filed on May 29, 2024, which is incorporated herein by reference in its entirety.

### TECHNICAL FIELD

Examples of the present application relate to the technical field of medical devices, and in particular to a magnetic resonance imaging method and a magnetic resonance imaging system.

### BACKGROUND

Magnetic resonance (MR) imaging systems are widely used in the field of medical diagnostics. Magnetic resonance systems generally have a main magnet, a gradient amplifier, a radio-frequency (RF) amplifier, a gradient coil, a transmit chain module, a transmit/receive coil, a receive chain module, etc. The transmit chain module generates a pulse signal and transmits the pulse signal to the transmit/receive coil. The transmit/receive coil generates a radio-frequency excitation signal to excite a scan subject to generate a magnetic resonance signal. After the excitation has ended, by way of spatial encoding, the transmit/receive coil acquires the magnetic resonance signal, and the magnetic resonance signal is filled into k-space, thereby reconstructing a medical image.

### SUMMARY

Provided in examples of the present application are a magnetic resonance imaging method and a magnetic resonance imaging system.

According to an aspect of the examples of the present application, a magnetic resonance imaging method is provided. The method includes adjusting a waveform of a first gradient pulse in a scan sequence according to a signal acquisition time window, wherein the signal acquisition time window at least comprises at least part of the gradient rise and gradient fall times of the first gradient pulse. The method further includes generating and transmitting a scan sequence with an adjusted waveform, acquiring a magnetic resonance signal in the signal acquisition time window, and reconstructing a magnetic resonance image according to the magnetic resonance signal.

According to an aspect of the examples of the present application, a magnetic resonance imaging system is provided. The system includes a scanning unit; and a controller, configured to perform the magnetic resonance imaging method according to the aforementioned aspect.

One of the beneficial effects of the examples of the present application is that the following: The waveform of the first gradient pulse in the scan sequence is adjusted according to the signal acquisition time window, and a diagnostic scan is performed on a site to be inspected by using the adjusted scan sequence, thereby reducing the repetition time (TR) of the scan sequence, improving the time resolution, improving the quality of a reconstructed image, and being not easily affected by the motion of an imaging subject.

With reference to the following description and drawings, specific embodiments of the examples of the present application are disclosed in detail, and the way in which the principles of the examples of the present application can be employed are illustrated. It should be understood that the embodiments of the present application are not limited in scope thereby. Within the scope of the spirit and clauses of the appended claims, the embodiments of the present application include many changes, modifications, and equivalents.

### BRIEF DESCRIPTION OF THE DRAWINGS

The included drawings are used to provide further understanding of the examples of the present application, which constitute a part of the description and are used to illustrate the embodiments of the present application and explain the principles of the present application together with textual description. Evidently, the drawings in the following description are merely some examples of the present application, and those of ordinary skill in the art may obtain other embodiments according to the drawings without involving inventive effort. In the drawings:

FIG. 1 is a schematic diagram of a magnetic resonance imaging system according to an embodiment of the present application;

FIG. 2 is a schematic diagram of a physical axis-based coordinate system P1 and a logical axis-based coordinate system L1 in an oblique scanning example according to an embodiment of the present application;

FIG. 3 is a schematic diagram of a magnetic resonance imaging method according to an embodiment of the present application;

FIG. 4 is a schematic diagram of a scan sequence according to an embodiment of the present application;

FIG. 5 is a schematic diagram of a signal acquisition time window according to an embodiment of the present application;

FIG. 6 is a schematic diagram of a signal acquisition time window according to an embodiment of the present application;

FIG. 7 is a schematic diagram of a signal acquisition time window according to an embodiment of the present application;

FIG. 8 is a schematic diagram of a signal acquisition time window according to an embodiment of the present application;

FIG. 9 is a schematic diagram of a signal acquisition time window according to an embodiment of the present application;

FIG. 10 is a schematic diagram of step 301 according to an embodiment of the present application;

FIG. 11 is a schematic diagram of an adjusted scan sequence according to an embodiment of the present application;

FIG. 12 is a schematic diagram of an adjusted scan sequence according to an embodiment of the present application; and

FIG. 13 is a flowchart of a magnetic resonance imaging method according to an embodiment of the present application.

### DETAILED DESCRIPTION

The aforementioned and other features of the examples of the present application will become apparent from the following description with reference to the drawings. In the description and drawings, specific embodiments of the present application are disclosed in detail, and part of the embodiments in which the principles of the examples of the present application may be employed are indicated. It should be understood that the present application is not limited to the described embodiments. On the contrary, the examples of the present application include all modifications, variations, and equivalents which fall within the scope of the appended claims.

In the examples of the present application, the terms “first”, “second”, etc. are used to distinguish between different elements in terms of appellation, but do not represent a spatial arrangement, a temporal order, or the like of these elements, and these elements should not be limited by these terms. The term “and/or” includes any one of and all combinations of one or more associated listed terms. The terms “include”, “comprise”, “have”, etc. refer to the presence of described features, elements, components, or assemblies, but do not exclude the presence or addition of one or more other features, elements, components, or assemblies.

In the examples of the present application, the singular forms “a” and “the”, etc., include plural forms, and should be broadly construed as “a type of” or “a class of” rather than being limited to the meaning of “one”. Furthermore, the term “the” should be construed as including both the singular and plural forms, unless otherwise specified in the context. In addition, the term “according to” should be construed as “at least in part according to . . . ” and the term “based on” should be construed as “based at least in part on . . . ”, unless otherwise specified in the context.

The features described and/or illustrated for one embodiment may be used in one or more other embodiments in an identical or similar manner, combined with features in other embodiments, or replace features in other embodiments. The term “include/comprise” when used herein refers to the presence of features, integrated components, steps, or assemblies, but does not exclude the presence or addition of one or more other features, integrated components, steps, or assemblies.

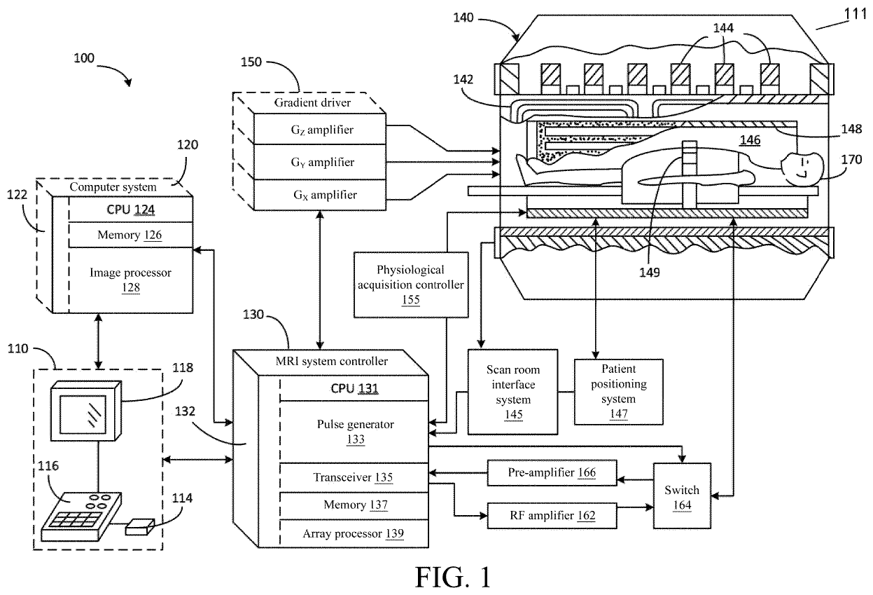

For ease of understanding, FIG. 1 shows a magnetic resonance imaging (MRI) system 100 according to some examples of the present invention.

The MRI system 100 includes a scanning unit 111. The scanning unit 111 is used to perform a magnetic resonance scan on a subject (for example, a human body) 170 to generate image data of a region of interest of the subject 170. The region of interest may be a predetermined anatomical site or anatomical tissue.

Operation of the MRI system 100 is controlled by an operator workstation 110, and the operator workstation 110 includes an input device 114, a control panel 116, and a display 118. The input device 114 may be a joystick, a keyboard, a mouse, a trackball, a touch-activated screen, voice control, or any similar or equivalent input device. The control panel 116 may include a keyboard, a touch-activated screen, voice control, a button, a slider, or any similar or equivalent control device. The operator workstation 110 is coupled to and communicates with a computer system 120, and the computer system enables an operator to control the generation and viewing of an image on the display 118. The computer system 120 includes a plurality of components that communicate with one another by way of an electrical and/or data connection module 122. The connection module 122 may employ a direct wired connection, a fiber optic connection, a wireless communication link, etc. The computer system 120 may include a central processing unit (CPU) 124, a memory 126, and an image processor 128. In some embodiments, the image processor 128 may be replaced with an image processing function implemented in the CPU 124. The computer system 120 may be connected to an archival media device, a persistent or backup memory, or a network. The computer system 120 may be coupled to and communicate with a separate MRI system controller 130.

The MRI system controller 130 includes a set of components that communicate with one another by way of an electrical and/or data connection module 132. The connection module 132 may employ a direct wired connection, a fiber optic connection, a wireless communication link, etc. The MRI system controller 130 may include a CPU 131, a sequential pulse generator 133 that communicates with the operator workstation 110, a transceiver (or an RF transceiver) 135, a memory 137, and an array processor 139. In some embodiments, the sequential pulse generator 133 may be integrated into a resonance assembly 140 of the scanning unit 111 of the MRI system 100. The MRI system controller 130 may receive a command from the operator workstation 110, and is coupled to the scanning unit 111, to indicate an MRI scan sequence that is to be performed during an MRI scan, so as to control the scanning unit 111 to execute the aforementioned magnetic resonance scan procedure. The MRI system controller 130 is further coupled to and communicates with a gradient driver system 150, and the gradient driver system is coupled to a gradient coil assembly 142 to generate a magnetic field gradient during the MRI scan.

The sequential pulse generator 133 may further receive data from a physiological acquisition controller 155, and the physiological acquisition controller receives signals from a plurality of different sensors (for example, electrocardiogram (ECG) signals from electrodes attached to a patient), the sensors being connected to the subject or patient 170 undergoing the MRI scan. The sequential pulse generator 133 is coupled to and communicates with a scan room interface system 145, and the scan room interface system receives signals from various sensors associated with the state of the resonance assembly 140. The scan room interface system 145 is further coupled to and communicates with a patient positioning system 147, and the patient positioning system sends and receives signals to control the movement of a patient table to a desired position to perform the MRI scan.

The MRI system controller 130 provides gradient waveforms to the gradient driver system 150, and the gradient driver system includes Gₓ (x direction), G_{y} (y direction), and G_{z} (z direction) amplifiers, etc. Each of the Gₓ, G_{y}, and G_{z} gradient amplifiers excites a corresponding gradient coil in the gradient coil assembly 142, to generate a magnetic field gradient used to spatially encode an MR signal during an MRI scan. The gradient coil assembly 142 is disposed within the resonance assembly 140, the resonance assembly further includes a superconducting magnet having a superconducting coil 144, and during operation, the superconducting coil provides a static uniform longitudinal magnetic field B₀ that runs through a cylindrical imaging volume 146. The resonance assembly 140 further includes an RF body coil 148, and in operation, the RF body coil provides a transverse magnetic field B₁, the transverse magnetic field B₁ being substantially perpendicular to the B₀ in the entire cylindrical imaging volume 146. The resonance assembly 140 may further include an RF surface coil 149, and the RF surface coil is used to image different anatomical structures of the patient undergoing the MRI scan. The RF body coil 148 and the RF surface coil 149 may be configured to operate in a transmit and receive mode, a transmit mode, or a receive mode.

The x direction may also be referred to as a frequency encoding direction or a kₓ direction in k-space. The y direction may be referred to as a phase encoding direction or a k_{y} direction in the k-space. Gₓ can be used for frequency encoding or signal readout, and is generally referred to as a frequency encoding gradient or a readout gradient. G_{y} can be used for phase encoding, and is generally referred to as a phase encoding gradient. G_{z} can be used for slice (layer) position selection to obtain k-space data. It should be noted that a layer selection direction, a phase encoding direction, and a frequency encoding direction may be modified according to actual requirements.

The subject or patient 170 of the MRI scan may be positioned within the cylindrical imaging volume 146 of the resonance assembly 140. The transceiver 135 in the MRI system controller 130 generates RF excitation pulses that are amplified by an RF amplifier 162 and provided to the RF body coil 148 by way of a transmit/receive switch (T/R switch) 164.

As described above, the RF body coil 148 and the RF surface coil 149 may be used to transmit an RF excitation pulse and/or receive obtained MR signals from the patient undergoing the MRI scan. MR signals emitted by excited nuclei in the patient of the MRI scan may be sensed and received by the RF body coil 148 or the RF surface coil 149 and sent back to a pre-amplifier 166 by way of the T/R switch 164. The T/R switch 164 may be controlled by a signal from the sequential pulse generator 133 to electrically connect, when in the transmit mode, the RF amplifier 162 to the RF body coil 148, and to connect, when in the receive mode, the pre-amplifier 166 to the RF body coil 148. The T/R switch 164 may further enable the RF surface coil 149 to be used in the transmit mode or the receive mode.

In some embodiments, the MR signals sensed and received by the RF body coil 148 or the RF surface coil 149 and amplified by the pre-amplifier 166 are stored as a raw k-space data array in the memory 137 for post-processing. A reconstructed magnetic resonance image may be obtained by transforming/processing the stored raw k-space data.

In some embodiments, the MR signals sensed and received by the RF body coil 148 or the RF surface coil 149 and amplified by the pre-amplifier 166 are demodulated, filtered and digitized in a receiving portion of the transceiver 135, and transmitted to the memory 137 in the MRI system controller 130. For each image that is to be reconstructed, the data is rearranged into a separate k-space data array, each of the separate k-space data arrays is inputted into the array processor 139, and the array processor is operated to transform the data into an array of image data by way of a Fourier transform.

The array processor 139 uses a transform method, most commonly a Fourier transform, to create images from the received MR signals. These images are transmitted to the computer system 120 and stored in the memory 126. In response to commands received from the operator workstation 110, the image data may be stored in a long-term memory, or may be further processed by the image processor 128 and transmitted to the operator workstation 110 for presentation on the display 118.

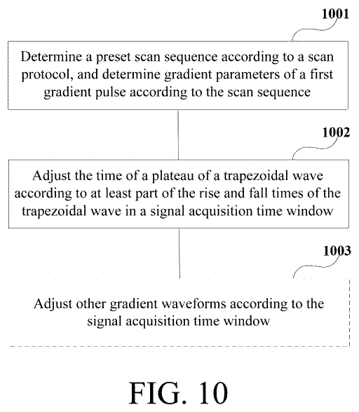

In various embodiments, components of the computer system 120 and the MRI system controller 130 may be implemented on the same computer system or on a plurality of computer systems. It should be understood that the MRI system 100 shown in FIG. 10 is intended for description. Suitable MRI systems may include more, fewer, and/or different components.

The MRI system controller 130 and the image processor 128 may separately or collectively include a computer processor and a storage medium. The storage medium records a predetermined data processing program that is to be executed by the computer processor. For example, the storage medium may store a program used to implement scanning (for example, a scan procedure and an imaging sequence), image reconstruction, image processing, etc. For example, the storage medium may store a program used to implement the magnetic resonance imaging method according to the examples of the present invention. The aforementioned storage medium may include, for example, a ROM, a floppy disk, a hard disk, an optical disk, a magneto-optical disk, a CD-ROM, or a non-volatile memory card.

The aforementioned “imaging sequence” (also referred to below as a scan sequence or a pulse sequence) is a combination of pulses that have specific amplitudes, widths, directions, and time sequences, and that are applied when a magnetic resonance imaging scan is performed. These pulses typically may include, for example, a radio-frequency pulse and a gradient pulse. The radio-frequency pulses may include, for example, radio-frequency excitation pulses, radio-frequency refocusing pulses, inverse recovery pulses, etc. The gradient pulses may include, for example, the aforementioned gradient pulse used for layer selection, gradient pulse used for phase encoding, gradient pulse used for frequency encoding, gradient pulse used for phase shifting (phase shift), gradient pulse used for dispersion of phases (dephasing), etc.

Typically, a plurality of scan sequences can be preset in the magnetic resonance system, so that the sequence suitable for clinical detection requirements can be selected. The clinical detection requirements may include, for example, an imaging site, an imaging function, an imaging effect, and the like.

In addition, the aforementioned gradient field can be considered as being oriented both in a physical plane and by the logical axis. In a physical sense, these fields are oriented orthogonally to each other to form a coordinate system, and the coordinate system can be rotated by appropriately manipulating a pulse current applied to an individual gradient field coil.

Thanks to the gradient system, magnetic resonance imaging can be implemented in any direction. Conventional anatomical sites may be scanned using conventional orthoaxial (tri-azimuthal) scans: transverse (TRA) or axial (AX), sagittal (SAG), and coronal (COR) scans. Some special complex sites may be scanned using an oblique scan, for example, a short-axis, four-chamber view is used for a cardiac scan.

In an orthoaxial scan, a physical gradient generated by a gradient amplifier can be configured with respect to an imaging system, so that a physical axis aligns/coincides with the logical axis when imaging is performed in an axial reference plane, a sagittal reference plane, and a coronal reference plane. For example, for axial imaging, coronal imaging, or sagittal imaging, the G_{z} amplifier can be configured to generate a slice selection gradient, the G_{y} amplifier can be configured to generate a phase-encoding gradient, and the Gₓ amplifier can be configured to generate a frequency-encoding gradient.

When an oblique scan is performed, the logical axis-based coordinate system is rotated by a certain angle relative to the physical axis-based coordinate system. In this case, the slice selection gradient, the frequency-encoding gradient, and the phase-encoding gradient need to be defined in the logical axis-based coordinate system. The slice selection gradient determines a slice of tissue or anatomical structure to be imaged in a patient. Therefore, a slice selection gradient field can be applied simultaneously with a selective radio frequency excitation pulse to excite spin volumes in oblique slices precessing at the same frequency. The slice thickness is determined by a bandwidth of the radio frequency excitation pulse and gradient strength in an entire field of view.

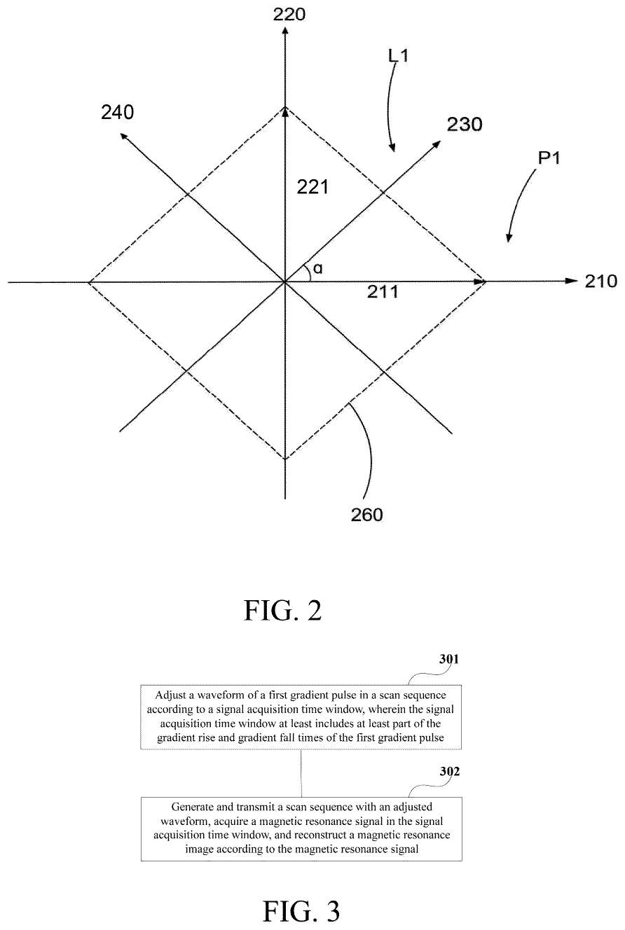

FIG. 2 shows a physical axis-based coordinate system P1 and a logical axis-based coordinate system L1 in an oblique scanning example. A first physical axis (X physical axis) 210, a second physical axis (Y physical axis) 220, a first logical axis (X logical axis) 230 rotated by an angle α (for example, 45 degrees) relative to the first physical axis 210, and a second logical axis (Y logical axis) 240 rotated by the angle α relative to the second physical axis 220 are defined. The X physical axis and the Y physical axis are driven by the Gₓ amplifier and the G_{y} amplifier respectively. Due to hardware limitations, a gradient emitted by the gradient system has limitations on the maximum amplitude and the maximum switching speed. For example, maximum amplitudes 211 and 221 that can be achieved by the Gₓ amplifier and the G_{y} amplifier respectively are shown in FIG. 2.

When the oblique scanning is performed, it is necessary to determine integral over time of each gradient in a gradient waveform on the logical axis (namely, an area of the gradient waveform) based on a preset scanning parameter (for example, slice direction, phase-encoding gradient value, TR, field of view (FOV), data acquisition bandwidth, data acquisition resolution, and the like), and a timing, an amplitude, a switching rate, and duration of the gradient are determined based on the area of the gradient. Then, the gradient amplifier can drive the gradient coil to emit a gradient field based on the timing, amplitude, switching rate, duration, and the like, the gradient coil to emit a gradient field.

Although the two logical axes 230 and 240 are shown in FIG. 2 for simplicity, it should be understood that, in practice, three logical axes may be used. For example, if three logical axes are used, then the box 260 can be changed to a cube.

In some examples, an initial gradient waveform can be designed/generated on the physical axis, converted onto the logical axis, and outputted. The outputted logical axis waveform can be re-converted into a physical axis waveform, so that the gradient amplifier can drive the gradient coil based on the converted physical axis waveform. During conversion of the waveform generated on the physical axis into a logical axis waveform, coordinate system conversion is performed. A relationship between the logical axis waveform and the physical axis waveform is as follows:

$$[ \begin{matrix}{G}_{logicX} \\ {G}_{logicY} \\ {G}_{logicZ}\end{matrix} ] = [ \begin{matrix}{a}_{11} & {a}_{12} & {a}_{13} \\ {a}_{21} & {a}_{22} & {a}_{23} \\ {a}_{31} & {a}_{32} & {a}_{33}\end{matrix} ] [ \begin{matrix}{G}_{p ℏ yX} \\ {G}_{p ℏ yY} \\ {G}_{p ℏ yZ}\end{matrix} ]$$

where G_{logicX}, G_{logicY}, and G_{logicZ} are gradient waveforms in the logical axis, G_{phyX}, G_{phyY}, and G_{phyZ} are gradient waveforms in the physical axis, and

$$[ \begin{matrix}{a}_{11} & {a}_{12} & {a}_{13} \\ {a}_{21} & {a}_{22} & {a}_{23} \\ {a}_{31} & {a}_{32} & {a}_{33}\end{matrix} ]$$

is a 3×3 rotation matrix. As is well known in the art, elements of the rotation matrix are determined by a slice orientation.

For both the orthoaxial scanning and oblique scanning, it is desirable to obtain the repetition time TR as short as possible to ensure the imaging quality. In response to this issue, the examples of the present application provide a magnetic resonance imaging method and a magnetic resonance imaging system. It should be noted that, in the following examples, oblique scanning is mainly used as an example for description, but the examples of the present application are not limited thereto.

Description is made below in conjunction with the examples.

An example of the present application provides a magnetic resonance imaging method. FIG. 3 is a schematic diagram of a magnetic resonance imaging method according to an embodiment of the present application. As shown in FIG. 3, the method includes: at step 301, adjusting a waveform of a first gradient pulse in a scan sequence according to a signal acquisition time window, wherein the signal acquisition time window at least includes at least part of the gradient rise and gradient fall times of the first gradient pulse. The method further includes at step 302, generating and transmitting a scan sequence with an adjusted waveform, acquiring a magnetic resonance signal in the signal acquisition time window, and reconstructing a magnetic resonance image according to the magnetic resonance signal.

In some examples, the scan sequence may be determined according to a preset scan protocol, the scan sequence at least includes a radio-frequency pulse and a gradient pulse, and the radio-frequency pulse may include an excitation pulse, a refocusing pulse, an inversion recovery pulse, a fat suppression pulse, and the like. The gradient pulse may include a first gradient pulse used for frequency encoding. Optionally, the gradient pulse may further include at least one of a second gradient pulse used for layer selection and a third gradient pulse used for phase encoding. For example, the scan sequence may include a gradient recalled echo (GRE) pulse sequence, a fast spin echo (FSE) pulse sequence, a fast imaging employing steady-state acquisition (FIESTA) sequence, a true fast imaging with steady-state precession (TrueFISP) sequence, and the like, but the examples of the present application are not limited thereto.

In some examples, the first gradient pulse includes at least one trapezoidal wave. The trapezoidal wave includes a time of a plateau tₚₗₐₜ, a rise time tₛₗₒₚ₁, and a fall time tₛₗₒₚ₂. A gradient value of the trapezoidal wave is a positive value. Optionally, the first gradient pulse further includes other gradient waveforms besides the trapezoidal wave. The other gradient waveforms include at least one of a first waveform located before the trapezoidal wave and a second waveform located after the trapezoidal wave.

For example, the first waveform may be a rewinder gradient waveform for pre-reversal so that the maximum signal may be acquired at a trapezoidal wave, and the second waveform may be a gradient waveform for removing a killer gradient. The gradient values of the first waveform and the second waveform may be negative values, and the first waveform and the second waveform may be triangular waves or the like, but the examples of the present application are not limited thereto.

In some examples, when the first gradient pulse includes a first waveform, a trapezoidal wave, and a second waveform, the first waveform, the trapezoidal wave, and the second waveform may be independently designed, or the first waveform, the second waveform, and the trapezoidal wave need to satisfy a specific relationship. For example, when the scan sequence is a FIESTA sequence, the sum of the areas of the first waveform, the trapezoidal wave, and the second waveform is 0, which is only an example herein, and the examples of the present application are not limited thereto.

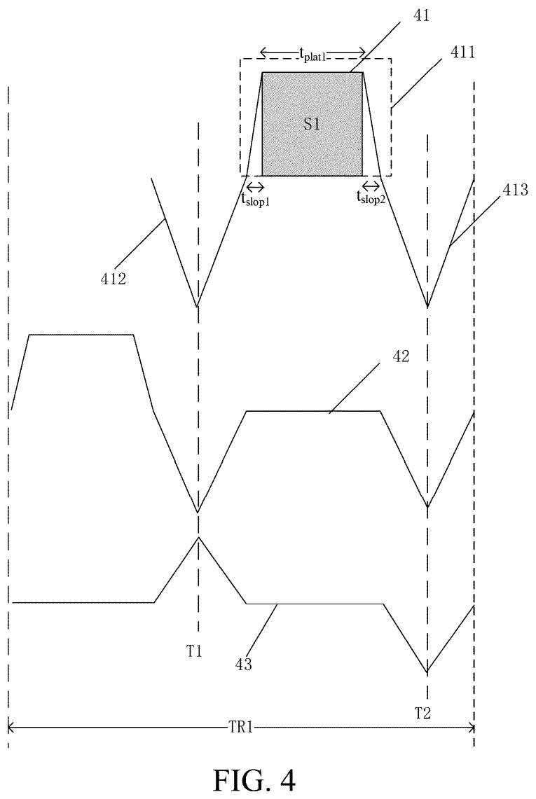

FIG. 4 is a schematic diagram of gradient pulses in a scan sequence according to an embodiment of the present application. Using the scan sequence in FIG. 4 as an example, the scan sequence includes a first gradient pulse 41, a second gradient pulse 42, and a third gradient pulse 43. The first gradient pulse 41 includes a trapezoidal wave 411, a first waveform 412, and a second waveform 413. The first waveform 412 and the second waveform 413 are triangular waves. The area of the trapezoidal wave 411 is S1, the area of the first waveform 412 is −S1/2, the area of the second waveform 413 is −S1/2, and the sum of the areas of the trapezoidal wave 411, the first waveform 412, and the second waveform 413 is 0.

In some examples, optionally, inflection points of gradient waveforms of the first gradient pulse, the second gradient pulse, and the third gradient pulse are set at the same time points. The term “inflection point” refers to a time when the amplitude value of a waveform starts to be converted from one changing trend (for example, a rising trend, a falling trend, or a plateau) to another changing trend. Using the scan sequence in FIG. 4 as an example, the first gradient pulse 41, the second gradient pulse 42, and the third gradient pulse 43 have common inflection points T1 and T2. The amplitudes of the first gradient pulse 41 and the second gradient pulse 42 start to fall before T1, and the amplitude values start to rise after reaching the minimum amplitude values at T1. The amplitude of the third gradient pulse 43 starts to rise before T1, and the amplitude value starts to fall after reaching the maximum amplitude value at T1. Similarly, the amplitudes of the first gradient pulse 41, the second gradient pulse 42, and the third gradient pulse 43 start to fall before T2, and the amplitude values start to rise to the zero amplitude after reaching the minimum amplitude values at T2.

By setting the inflection points at the same time points, the inflection points of the gradient waveforms on both the physical axis and the logical axis are at the same time points during the oblique scanning, thereby ensuring that the gradient waveforms can be maintained when the physical axis is converted to the logical axis. Thus, the gradient transmitting capability of hardware can be utilized to the maximum extent, and a gradient waveform with a large amplitude and the small repetition time TR can be obtained.

The inventor found that, in the existing orthoaxial scanning or oblique scanning, when a radio-frequency coil and a gradient coil are used to transmit the scan sequence to apply a magnetic field gradient and a radio-frequency pulse, a receiving coil does not always acquire a magnetic resonance signal, but only acquires (receives) the magnetic resonance signal in a preset signal acquisition time window. The signal acquisition time window represents a time period in which the magnetic resonance signal is recorded. Using the scan sequence in FIG. 4 as an example, currently the signal acquisition time window is usually designed to be located at the plateau of the trapezoidal wave of the first gradient pulse. The examples of the present application further provide a method combined with slope sampling, so that the signal acquisition time window includes at least part of the rise and fall times of the trapezoidal wave besides the plateau, and the waveform of the first gradient pulse in the scan sequence is adjusted according to the signal acquisition time window, thereby reducing the repetition time (TR) of the scan sequence, improving the time resolution, and improving the quality of a reconstructed image. The detailed description is provided below.

In some examples, the signal acquisition time window may be set to include the plateau of the trapezoidal wave in the first gradient pulse and at least part of the rise and fall times of the trapezoidal wave. The signal acquisition time window may be set at each trapezoidal wave or part of trapezoidal waves of the first gradient pulse, which is not limited in the examples of the present application.

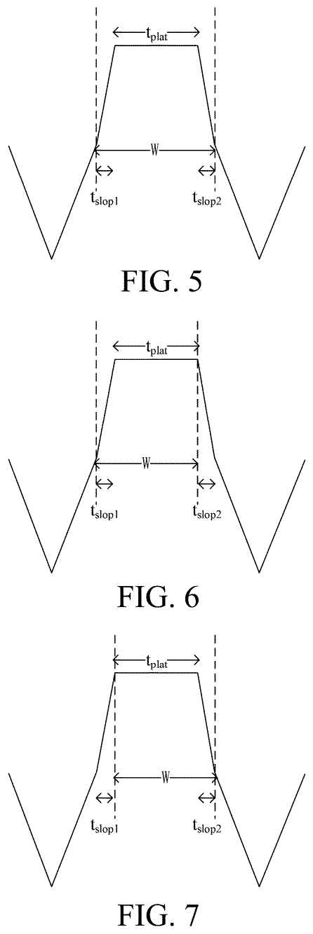

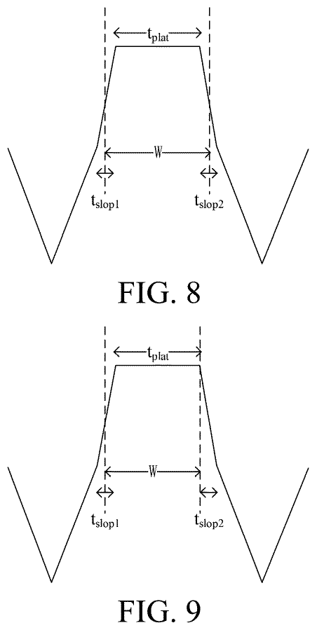

FIG. 5 to FIG. 9 are schematic diagrams of signal acquisition time windows W according to the embodiments of the present application. As shown in FIG. 5, the signal acquisition time window includes tₛₗₒₚ₁+tₚₗₐₜ+tₛₗₒₚ₂. As shown in FIG. 6, the signal acquisition time window includes tₛₗₒₚ₁+tₚₗₐₜ. As shown in FIG. 7, the signal acquisition time window includes tₛₗₒₚ₂+tₚₗₐₜ. As shown in FIG. 8, the signal acquisition time window includes tₚₗₐₜ and part of tₛₗₒₚ₁+tₛₗₒₚ₂ (e.g., half, i.e., tₛₗₒₚ₁/2+tₚₗₐₜ+tₛₗₒₚ₂/2). As shown in FIG. 9, the signal acquisition time window includes tₚₗₐₜ and part of tₛₗₒₚ₁. More examples are omitted herein. The aforementioned signal acquisition time window may be preset according to a scan protocol and the type of a scan sequence, which is not limited in the examples of the present application. The signal acquisition time window is set to include a certain portion of the trapezoidal wave, rather than setting the absolute time of the signal acquisition time window. After the trapezoidal wave is adjusted subsequently, the signal acquisition time window is also updated. For example, after the plateau of the trapezoidal wave is shortened, the signal acquisition time window is also shortened.

For a preset scan sequence, especially for the scan sequence with inflection points set at the same time points in FIG. 4 above, the second gradient pulse and the third gradient pulse are not included in the rise and fall times of the trapezoidal wave of the first gradient pulse. Hence, the second gradient pulse and the third gradient pulse are not included in the entire signal acquisition time window. In other words, no phase or layer selection encoding gradient exists in the entire signal acquisition time window. Taking advantage of this, signal acquisition can be supported during the rise and fall times of the trapezoidal wave. Namely, data sampling (slope sampling) may be performed during the gradient rise and fall time, to improve the signal acquisition efficiency and further reduce the TR.

In some examples, FIG. 10 is a schematic diagram of step 301 according to an example of the present application. As shown in FIG. 10, the adjusting a waveform of a first gradient pulse in a scan sequence according to a signal acquisition time window in step 301 includes: 1001, determining a preset scan sequence according to a scan protocol, and determining gradient parameters of a first gradient pulse according to the scan sequence, for example, tₛₗₒₚ₁, tₚₗₐₜ₁, and tₛₗₒₚ₂; and 1002, adjusting the time of a plateau of a trapezoidal wave according to at least part of the rise and fall times of the trapezoidal wave in a signal acquisition time window. The time of the plateau shortened is calculated according to the proportion of the slope sampling in the signal acquisition time window, and the adjusted time of the plateau of the trapezoidal wave of the first gradient pulse is tₚₗₐₜ₂. The principle of adjustment includes the following: the gradient area corresponding to the signal acquisition time window after the waveform is adjusted is the same as the plateau area of the trapezoidal wave before the waveform is adjusted, but the maximum gradient value of the plateau is unchanged.

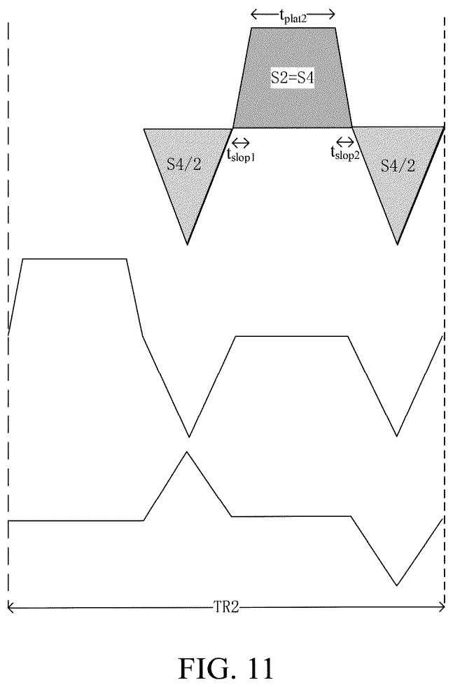

The signal acquisition time window in FIG. 5 is used as an example for description. FIG. 11 is a schematic diagram of an adjusted scan sequence according to an embodiment of the present application, corresponding to the scan sequence before adjustment in FIG. 4. As shown in FIG. 4, the plateau area of the trapezoidal wave before the waveform is adjusted is S1=Gₘₐₓ×tₚₗₐₜ₁. As shown in FIG. 11, after calculation and adjustment are performed according to tₛₗₒₚ₁ and tₛₗₒₚ₂, the time of a plateau of the trapezoidal wave of the first gradient pulse is tₚₗₐₜ₂. The gradient area corresponding to the signal acquisition time window after the waveform is adjusted is equivalent to the area of the trapezoidal wave after the waveform is adjusted, with S2=Gₘₐₓ×(tₚₗₐₜ₂+tₚₗₐₜ₂+tₛₗₒₚ₁+tₛₗₒₚ₂)/2. S1 is the same as S2, which is equivalent to tₚₗₐₜ₁=(tₚₗₐₜ₂+tₚₗₐₜ₂+tₛₗₒₚ₁+tₛₗₒₚ₂)/2, where tₛₗₒₚ₁, tₚₗₐₜ₁, and tₛₗₒₚ₂ are known, and thus tₚₗₐₜ₂ can be calculated. The signal acquisition time window after the waveform is adjusted (updated) is tₛₗₒₚ₁+tₚₗₐₜ₂+tₛₗₒₚ₂. The repetition time TR2 is reduced compared to the TR1 in FIG. 4.

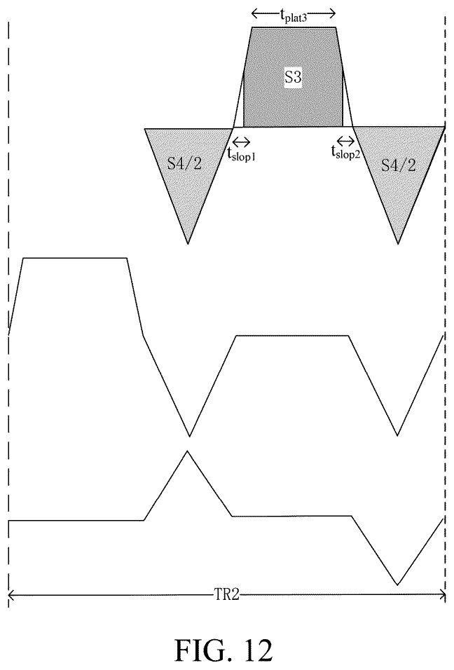

The signal acquisition time window in FIG. 8 is used as an example for description. FIG. 12 is a schematic diagram of an adjusted scan sequence according to an embodiment of the present application, corresponding to the scan sequence before adjustment in FIG. 4. As shown in FIG. 4, the plateau area of the trapezoidal wave before the waveform is adjusted is S1=Gₘₐₓ×tₚₗₐₜ₁. As shown in FIG. 12, after calculation and adjustment are performed according to tₛₗₒₚ₁ and tₛₗₒₚ₂, the time of a plateau of the trapezoidal wave of the first gradient pulse is tₚₗₐₜ₃. The gradient area corresponding to the signal acquisition time window after the waveform is adjusted is equivalent to the area of the trapezoidal wave after the waveform is adjusted, with S3=Gₘₐₓ×(tₚₗₐₜ₃+tₚₗₐₜ₃+tₛₗₒₚ₁+tₛₗₒₚ₂)/2−Gₘₐₓ/2×tₛₗₒₚ₁/2−Gₘₐₓ/2×tₛₗₒₚ₂/2. S1 is the same as S3, which is equivalent to tₚₗₐₜ₁=(tₚₗₐₜ₃+tₚₗₐₜ₃+tₛₗₒₚ₁+tₛₗₒₚ₂)/2−tₛₗₒₚ₁/4−tₛₗₒₚ₂/4, where tₛₗₒₚ₁, tₚₗₐₜ₁, and tₛₗₒₚ₂ are known, and thus tₚₗₐₜ₃ can be calculated. The signal acquisition time window after the waveform is adjusted (updated) is tₛₗₒₚ₁/2+tₚₗₐₜ₃+tₛₗₒₚ₂/2. The repetition time TR2 is reduced compared to the TR1 in FIG. 4.

In some examples, as shown in FIG. 10, optionally, step 301 may further include: 1003, adjusting other gradient waveforms according to the signal acquisition time window. For example, the first waveform and the second waveform are adjusted according to the signal acquisition time window. When the first waveform, the second waveform, and the trapezoidal wave have an association relationship, for example, when the scan sequence is a FIESTA sequence, the sum of the areas of the first waveform, the trapezoidal wave, the second waveform is 0, the adjusted trapezoidal wave area is S4=Gₘₐₓ×(tₚₗₐₜ₂+tₚₗₐₜ₂+tₛₗₒₚ₁+tₛₗₒₚ₂)/2, and the areas of the first waveform and the second waveform are equal to S4/2. At least one of the maximum amplitude values and durations of the first waveform and the second waveform is adjusted, so that the adjusted areas of the first waveform and the second waveform are equal to S4/2.

It should be noted that, optionally, if the durations of the first waveform and the second waveform are adjusted, the second gradient pulse and the third gradient pulse need to be adaptively adjusted, so as to set inflection points of the gradient waveforms of the first gradient pulse, the second gradient pulse, and the third gradient pulse to the same time points.

As shown in FIG. 4, FIG. 11, and FIG. 12, such slope sampling can shorten the time of a plateau of the trapezoidal wave, thereby effectively shortening the TR. Especially for a scenario of a small field of view (FOV) or a large sampling bandwidth, the amplitude value of the required trapezoidal wave is correspondingly larger, and signal acquisition during the rise and fall is more beneficial to shortening the TR.

In some examples, in 302, after the waveform is adjusted, a gradient amplifier is driven by the adjusted waveform, so that a gradient coil applies a magnetic field gradient according to the adjusted scan sequence. A receiving coil acquires (receives) a magnetic resonance signal in the updated signal acquisition time window, and a magnetic resonance image is reconstructed according to the magnetic resonance signal. For the image reconstruction method, the related art may be referred to. The data of the slope sampling cannot be directly used in a Fourier transform, and the slope sampling needs to be implemented based on high-fidelity gradient and then by rasterization processing (by calculating a predicted error and then using interpolation processing), and descriptions thereof are omitted herein.

In some examples, if switching to a next scan subject to be scanned, then the aforementioned imaging method is performed again.

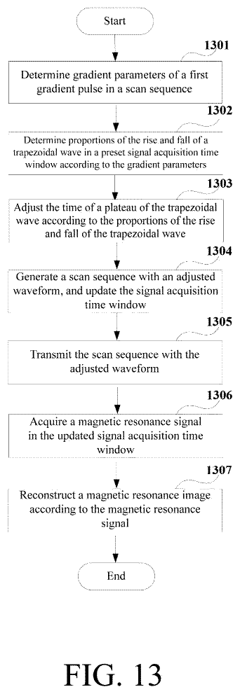

FIG. 13 is a flowchart of a magnetic resonance imaging method according to an embodiment of the present application. As shown in FIG. 13, the method includes: at step 1301, determining gradient parameters of a first gradient pulse in a scan sequence and at step 1302, determining the proportions of the rise and fall of a trapezoidal wave in a preset signal acquisition time window according to the gradient parameters. The method also includes at step 1303, adjusting the time of a plateau of the trapezoidal wave according to the proportions of the rise and fall of the trapezoidal wave, and optionally, further adjusting a first waveform and a second waveform and at step 1304, generating a scan sequence with an adjusted waveform, and updating the signal acquisition time window. At step 1305 the scan sequence with the adjusted waveform is transmitted and at step 1306, a magnetic resonance signal in the updated signal acquisition time window is acquired. Finally, the method includes at step 1307, reconstructing a magnetic resonance image according to the magnetic resonance signal.

Specific implementations of 1301 to 1307 are as described above, and are not be repeated herein. It should be noted that the waveforms in each of the above drawings are logical axis waveforms.

Through the above examples, the waveform of the first gradient pulse in the scan sequence is adjusted according to the signal acquisition time window, and a diagnostic scan is performed on a site to be inspected by using the adjusted scan sequence, thereby reducing the repetition time (TR) of the scan sequence, improving the time resolution, improving the quality of a reconstructed image, and being not easily affected by the motion of an imaging subject.

The examples of the present application further provide a gradient waveform determining method, the method including: adjusting a waveform of a first gradient pulse in a gradient sequence according to a signal acquisition time window, wherein the signal acquisition time window at least includes at least part of the gradient rise and gradient fall times of the first gradient pulse; and driving a gradient amplifier by the adjusted gradient sequence. The gradient amplifier excites the corresponding gradient coil to generate a magnetic field gradient for encoding an MR signal space during an MRI scan. For the specific embodiment, reference may be made to the foregoing examples, which will not be repeated here.

The examples of the present application further provide a magnetic resonance imaging system. The configuration of the magnetic resonance imaging system is as shown in FIG. 1, and repeated parts are not described herein.

In some examples, unlike the foregoing magnetic resonance imaging system in FIG. 1, the controller 130 is configured to perform the foregoing magnetic resonance imaging method.

In some examples, the controller 130 (or a processor) includes a computer processor and a storage medium. The storage medium records a predetermined data processing program to be executed by the computer processor. For example, the storage medium may store a program for implementing scan processing (e.g., including waveform design/conversion, and the like), image reconstruction, image processing, and the like. For example, the storage medium may store a program for implementing the gradient waveform determining method according to the examples of the present application. The specific embodiments thereof are as described above, and will not be repeated here.

The aforementioned storage medium may include, for example, a ROM, a floppy disk, a hard disk, an optical disk, a magneto-optical disk, a CD-ROM, or a non-volatile memory card.

The examples of the present application further provide a computer-readable program. When the program is executed in an apparatus or an MRI system, the program causes a computer to perform, in the apparatus or the MRI system, the method according to the aforementioned examples.

The examples of the present application further provide a storage medium having a computer-readable program stored therein. The computer-readable program causes a computer to perform, in an apparatus or an MRI system, the method according to the aforementioned examples.

The above apparatus and method of the present application can be implemented by hardware, or can be implemented by hardware in combination with software. The present application relates to such a computer-readable program that when executed by a logic component, the program causes the logic component to implement the foregoing apparatus or a constituent component, or causes the logic component to implement various methods or steps as described above. The present application further relates to a storage medium for storing the above program, such as a hard disk, a magnetic disk, an optical disc, a DVD, a flash memory, etc.

The method/apparatus described with reference to the examples of the present application may be directly embodied as hardware, a software module executed by a processor, or a combination of the two. For example, one or more of the functional block diagrams and/or one or more combinations of the functional block diagrams shown in the figures may correspond to either software modules or hardware modules of a computer program flow. The foregoing software modules may respectively correspond to the steps shown in the figures. The foregoing hardware modules may be implemented, for example, by consolidating the foregoing software modules by using a field-programmable gate array (FPGA).

The software modules may be located in a RAM memory, a flash memory, a ROM memory, an EPROM memory, an EEPROM memory, a register, a hard disk, a removable disk, a CD-ROM, or any storage medium in other forms known in the art. The storage medium may be coupled to a processor, so that the processor can read information from the storage medium and can write information into the storage medium. Alternatively, the storage medium may be a constituent component of the processor. The processor and the storage medium may be located in an ASIC. The software module may be stored in a memory of a mobile terminal, and may also be stored in a memory card that can be inserted into a mobile terminal. For example, if a device (such as a mobile terminal) uses a large-capacity MEGA-SIM card or a large-capacity flash memory apparatus, then the software modules may be stored in the MEGA-SIM card or the large-capacity flash memory apparatus.

One or more of the functional blocks and/or one or more combinations of the functional blocks shown in the drawings may be implemented as a general-purpose processor, a digital signal processor (DSP), an application-specific integrated circuit (ASIC), a field-programmable gate array (FPGA) or other programmable logic devices, a discrete gate or transistor logic device, a discrete hardware assembly, or any appropriate combination thereof, which is used for implementing the functions described in the present application. The one or more functional blocks and/or the one or more combinations of the functional blocks shown in the drawings may alternatively be implemented as a combination of computing devices, such as a combination of a DSP and a microprocessor, a plurality of microprocessors, one or more microprocessors in communication combination with a DSP, or any other such configuration.

The present application is described above with reference to specific embodiments. However, it should be clear to those skilled in the art that the foregoing description is merely illustrative and is not intended to limit the scope of protection of the present application. Various variations and modifications may be made by those skilled in the art according to the principle of the present application, and said variations and modifications also fall within the scope of the present application.

1. A magnetic resonance imaging method, characterized by comprising:
adjusting a waveform of a first gradient pulse in a scan sequence according to a signal acquisition time window, wherein the signal acquisition time window at least comprises at least part of the gradient rise and gradient fall times of the first gradient pulse; and
generating and transmitting a scan sequence with an adjusted waveform, acquiring a magnetic resonance signal in the signal acquisition time window, and reconstructing a magnetic resonance image according to the magnetic resonance signal.

2. The method according to claim 1, wherein the first gradient pulse comprises at least one trapezoidal wave; and
the signal acquisition time window at least comprises at least part of the rise and fall times of the trapezoidal wave.

3. The method according to claim 2, wherein the adjusting a waveform of a first gradient pulse in a scan sequence according to a signal acquisition time window comprises: adjusting the time of a plateau of the trapezoidal wave according to the at least part of the rise and fall times of the trapezoidal wave in the signal acquisition time window.

4. The method according to claim 1, wherein the gradient area corresponding to the signal acquisition time window after the waveform is adjusted is the same as the plateau area of a trapezoidal wave before the waveform is adjusted.

5. The method according to claim 2, wherein the first gradient pulse further comprises other gradient waveforms besides the trapezoidal wave; and
the adjusting a waveform of a first gradient pulse in a scan sequence according to a signal acquisition time window further comprises:
adjusting the other gradient waveforms according to the signal acquisition time window.

6. The method according to claim 1, wherein the scan sequence further comprises at least one of a second gradient pulse and a third gradient pulse; and
the second gradient pulse and the third gradient pulse are not comprised in the signal acquisition time window.

7. The method according to claim 6, wherein the second gradient pulse and the third gradient pulse are not comprised in the rise and fall times of the trapezoidal wave of the first gradient pulse.

8. The method according to claim 6, wherein inflection points of gradient waveforms of the first gradient pulse, the second gradient pulse, and the third gradient pulse are set at the same time points.

9. The method according to claim 1, wherein the first gradient pulse is a gradient pulse used for frequency encoding.

10. A magnetic resonance imaging system, characterized by comprising:
a scanning unit; and
a controller, configured to perform the magnetic resonance imaging method according to claim 1.
